(19) United States
(12) Patent Application Publication
(10) Pub. No.: US 2023/0297032 A1
(43) Pub. Date: Sep. 21, 2023

(54) Dial Decoration Method And Dial

(71) Applicant: SEIKO EPSON CORPORATION, Tokyo (JP)

(72) Inventors: Toshinori NAKAZAWA, Matsumoto (JP); Hironori HASEI, Azumino (JP); Toshimitsu HIRAI, Hokuto (JP); Hirofumi KUROSAWA, Tatsuno (JP)

(21) Appl. No.: 18/184,425

(22) Filed: Mar. 15, 2023

(30) Foreign Application Priority Data
Mar. 16, 2022 (JP) 2022-041091

(51) Int. Cl. G04D 3/00; B41J 3/407; G04B 19/06

(52) U.S. Cl. CPC G04D 3/0048; B41J 3/4071; G04B 19/06

(57) ABSTRACT

A dial decoration method of the present disclosure is a dial decoration method including a base formation step of forming a pattern shape on a base material and using the pattern shape as a base, and a printed layer formation step of forming a printed layer on a surface side of the base, and the printed layer formation step includes printing a pattern shape, to form the printed layer, by changing a density of dots of ink ejected by an inkjet method.

The present application is based on, and claims priority from JP Application Serial Number 2022-041091, filed Mar. 16, 2022, the disclosure of which is hereby incorporated by reference herein in its entirety.

### BACKGROUND

### 1. Technical Field

The present disclosure relates to a dial decoration method and a dial.

### 2. Related Art

Published Japanese Translation No. 2021-510820 of the PCT International Publication discloses a dial of a timepiece including a support and a mother-of-pearl sheet. The mother-of-pearl sheet includes a front surface and a rear surface that faces the support and has a pattern printed thereon. The mother-of-pearl sheet has a thickness of 50 μm to 100 μm so that the pattern printed on the rear surface of the mother-of-pearl sheet can be seen through the mother-of-pearl under normal lighting conditions.

In the dial disclosed in Published Japanese Translation No. 2021-510820 of the PCT International Publication, a pattern is printed on the rear surface of the mother-of-pearl sheet serving as a base by silk screen printing, photolithography, inkjet printing, or the like. That is, it is difficult for a user to visually recognize the printed pattern by visually recognizing the printed pattern through the base. For this reason, there is a demand for a dial decoration method and a dial which are capable of printing a pattern on the surface side of a base and realizing a complex design.

### SUMMARY

A dial decoration method of the present disclosure is a dial decoration method including a base formation step of forming a pattern shape on a base material and using the pattern shape as a base, and a printed layer formation step of forming a printed layer on a surface side of the base, and the printed layer formation step includes printing a pattern shape, to form the printed layer, by changing a density of a plurality of dots of ink ejected by an inkjet method.

A dial of the present disclosure includes a base material including a surface on which a pattern shape used as a base is formed, and a printed layer formed on a surface side of the base, wherein a pattern shape is printed on the printed layer by changing a density of the plurality of dots of ink ejected by an inkjet method.

### BRIEF DESCRIPTION OF THE DRAWINGS

FIG. 1 is a cross-sectional view illustrating a layer configuration of a dial according to an embodiment.

FIG. 2 is a flowchart illustrating a dial decoration method according to the embodiment.

FIG. 3 is a diagram illustrating reflected light when the dial according to the embodiment is viewed in a front view.

FIG. 4 is a diagram illustrating reflected light when the dial according to the embodiment is viewed in a perspective view.

FIG. 5 is a diagram illustrating the dial when viewed in a front view, a perspective view when viewed at 50 degrees, and a perspective view when viewed at 80 degrees.

FIG. 6 is a diagram showing a first decoration example of the dial.

FIG. 7 is a diagram showing a second decoration example of the dial.

### DESCRIPTION OF EXEMPLARY EMBODIMENTS

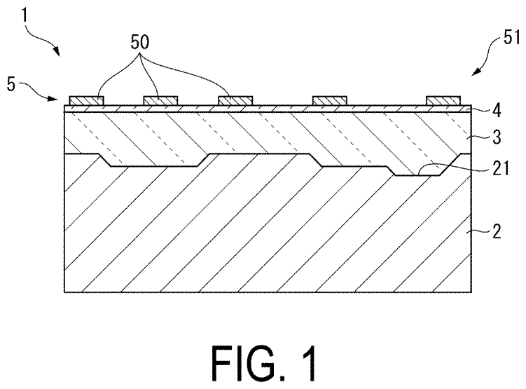

A dial decoration method and a dial according to an embodiment will be described with reference to FIGS. 1 to 5. FIG. 1 is a cross-sectional view illustrating a layer configuration of a dial 1.

The dial 1 includes a base material 2 having a pattern shape 21 serving as a base formed at a surface thereof, a light-transmissive layer 3 laminated on the surface of the base material 2, a liquid repellent layer 4 formed by performing a liquid repellent treatment on the surface of the light-transmissive layer 3, and a printed layer 5 formed at the surface of the liquid repellent layer 4 using ink 50 ejected by an inkjet method. The printed layer 5 is formed at the surface side of the base material 2, that is, the pattern shape 21 serving as a base. In addition, the printed layer 5 is formed by printing a pattern shape 51 by changing the density of dots of the ink 50. That is, the pattern shape 51 of the printed layer 5 is formed by a dot pattern which is an ejection pattern of the ink 50.

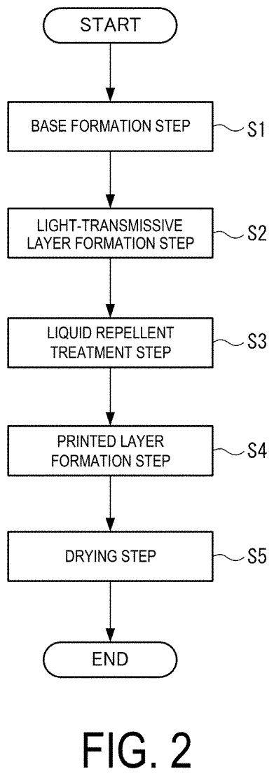

Next, a decorating method for forming a pattern shape at the dial 1 will be described with reference to a flowchart of FIG. 2.

When a decorating method for the dial 1 is started, first, a base formation step S1 of forming the pattern shape 21 on the surface of the base material 2 of the dial 1 by plating, engraving, coating, or the like and using the pattern shape 21 as a base is performed. As the base material 2, a metal plate such as brass, nickel silver, aluminum, or stainless steel, a hard plastic plate, a ceramic plate, or the like can be used, and in particular, when the base material 2 is constituted by a metal plate, the base material 2 can be designed to have a higher class feeling than in a case where plastic is used, and it is possible to further improve a design property by a combination of the pattern shape 21 of the base material 2 and the pattern shape 51 of the printed layer 5.

Further, in a case where the pattern shape 21 is formed by providing irregularities on the surface of the base material 2 by engraving or the like, a base in which the pattern shape 21 is formed is configured by an irregular surface of the base material 2. In a case where the pattern shape 21 is formed at the surface of the base material 2 by plating, coating, or the like, a base is constituted by a plated or coated layer.

After the base formation step S1 is performed, a light-transmissive layer formation step S2 for forming the light-transmissive layer 3 by applying a light transmissive resin to the surface of the base material 2 is performed. As the light transmissive resin, resin materials such as transparent, pearlescent, and colored transparent resin materials can be used, and for example, an acrylic resin, an epoxy resin, or the like can be used. A thickness dimension of the light-transmissive layer 3 is, for example, 40 μm or more and 100 μm or less.

As a method of applying a light transmissive resin to the surface of the base material 2, a method of applying a light transmissive resin by spraying, a method of ejecting and applying a light transmissive resin by an inkjet method, or the like can be used.

After the light-transmissive layer formation step S2 is performed, a liquid repellent treatment step S3 for performing a liquid repellent treatment on the surface of the light-transmissive layer 3 is performed. For the liquid repellent treatment, for example, a method of replacing a portion of a molecular structure of a resin exposed on the surface of the light-transmissive layer 3 with fluorine using an atmospheric-pressure plasma may be performed. The liquid repellent layer 4 having liquid repellent properties is formed at the surface of the light-transmissive layer 3 by such a liquid repellent treatment.

After the liquid repellent treatment step S3 is performed, a printed layer formation step S4 for printing the pattern shape 51 on the surface of the liquid repellent layer 4 by an inkjet method to form the printed layer 5 is performed. As the ink 50 ejected by an inkjet method in order to form the printed layer 5, water-based ink, solvent-based ink, UV curing-type ink, or the like can be used. In the ink 50, pigments, dyes, microparticles, resins, and the like are dispersed in a solvent, and for example, silver nanoparticle ink which is a water-based ink, epoxy resin ink which is a solvent-based clear ink, titanium oxide ink which is a solvent-based white ink, carbon ink which is a solvent-based black ink, or the like can be used. In addition, as the ink 50, transparent ink such as titanium oxide ink may be used, or non-transparent ink such as silver nanoparticle ink may be used.

Here, in a case where the printed layer 5 is formed with silver nanoparticle ink, it is preferable that the base of the base material 2 be formed in a dark color. Dark colors, such as black, green, navy blue, and purple, are colors that differ from a white color due to their lightness and chroma, and thus the silver nanoparticle ink, which is a silver ink, is easily visually recognized, and the pattern shape of the printed layer can also be easily visually recognized.

Further, in a case where the printed layer 5 is formed with transparent ink, it is preferable that the base of the base material 2 be formed in a similar color to that of the transparent ink. For example, in a case where the printed layer 5 is formed with titanium oxide ink which is a transparent ink, the titanium oxide ink is a solvent-based white ink, and thus it is preferable that the color of the base be also a white-based color. By forming the base and ink in similar colors, the color of the base and the color of the transparent ink are viewed to overlap each other, and thus it is possible to express a high-quality pattern shape in which two types of textures are mixed. Note that the transparent ink may be ink other than titanium oxide ink, which is a white ink, and it is preferable that the ink have high brightness, particularly in that the pattern shape of the base is easily visually recognized. In addition, as the printed layer 5, pattern shapes of a plurality of colors may be printed using a plurality of types of ink. As the plurality of types of ink, a plurality of types of transparent ink may be used, a region in which transparent ink is printed and a region in which non-transparent ink is printed may be distinguished from each other, or a plurality of types of non-transparent ink may be printed in different regions.

Dots of the ink 50 which are ejected by an inkjet method and attached to the surface of the liquid repellent layer 4 are formed in a circular design in a front view when viewed from a direction orthogonal to the surface of the dial 1. The diameter of the dot of the ink 50 has a size of 10 μm or more and 70 μm or less, and preferably has a size of 20 μm or more and 50 μm or less. When the diameter of the dot of the ink 50 has a size of 70 μm or less, one dot itself is printed with a dot size that cannot be visually recognized by a user's naked eye, and thus, when the user visually recognizes the pattern shape 51 of the printed layer 5, the dots can be recognized as an aggregate of dots, that is, a dot pattern shape. In addition, when the diameter of the dot of the ink 50 is 10 μm or more, the ink 50 can be stably ejected to an accurate position by an inkjet method. For this reason, for example, the ink 50 can be repeatedly ejected to the same position.

The thickness dimension of the printed layer 5 is, for example, 0.1 μm or more and 10 μm or less.

After the printed layer formation step S4 is performed, a drying step S5 for drying the ink 50 of the printed layer 5 is performed. In the drying step S5, the ink 50 is dried using a hot plate, an oven, a far-infrared heating furnace, a vacuum dryer, or the like. Note that, in a case where the ink 50 is UV curing system ink, the ink 50 is cured by UV irradiation in the drying step S5. That is, the drying step S5 is a step of fixing the ink 50 attached to the surface of the liquid repellent layer 4 to the surface of the liquid repellent layer 4 by drying and curing.

Visual Effect of Dial

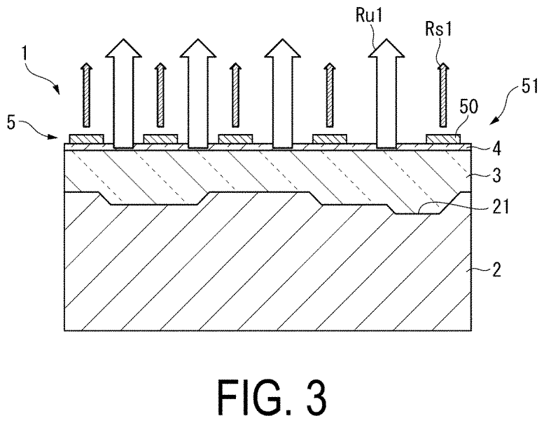

The appearance of a pattern shape when the dial 1 decorated in the above-described steps is visually recognized will be described with reference to FIGS. 3 to 5. In the present embodiment, the dial 1 is provided with the pattern shape 21 formed at the surface of the base material 2 and the pattern shape 51 formed by a dot pattern which is an ejection pattern of the ink 50 of the printed layer 5. Further, when comparing the front view of the dial 1 from a direction of 0 degrees which is a direction orthogonal to the surface and the perspective view of the dial 1 from an oblique direction, the pattern shape 21 of the base material 2 is more likely to be visually recognized in the front view than in the perspective view, and conversely, the pattern shape 51 of the printed layer 5 is more likely to be visually recognized in the perspective view than in the front view.

The visual effects are based on the following three reasons. The first reason is because Ls1<Ls2 when the luminance of reflected light Rs1 in a direction of 0 degrees in the printed layer 5 is Ls1, and the luminance of reflected light Rs2 in an oblique direction is Ls2.

The second reason is because Ls/Lu is larger in the perspective view than in the front view when the luminance of the printed layer 5 is Ls, and the luminance of the base material 2 is Lu.

The third reason is because the area of the dots of the ink 50 with respect to the exposed area of the base material 2 is larger in the perspective view than in the front view.

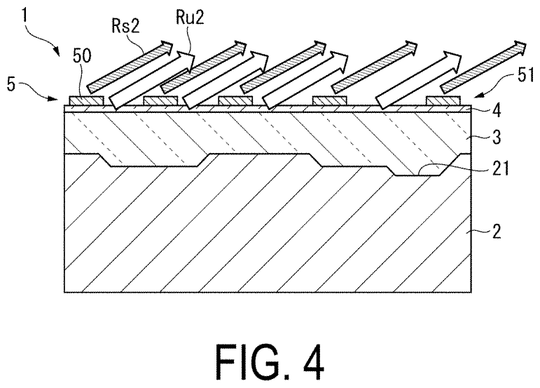

As illustrated in FIGS. 3 and 4, the luminance of reflected light of the printed layer 5 is lower in the direction of 0 degrees than in the oblique direction. That is, when the luminance of the reflected light Rs1 in the direction of 0 degrees of the printed layer 5, that is, the luminance in the front view, is Ls1, and the luminance of the reflected light Rs2 in the oblique direction, that is, the luminance in the perspective view, is Ls2, Ls1 <Ls2.

In addition, the amount of reflected light of the base material 2 constituted by a metal plate or the like is sufficiently larger than the amount of light reflected by the printed layer 5. For example, when the luminance of the reflected light Ru1 in the direction of 0 degrees of the base material 2, that is, the luminance in the front view is Lu1, Ls1 >>Lu1.

Thus, the amount of light reflected from the base material 2 is sufficiently large, and thus the pattern shape 21 formed at the surface of the base material 2 is likely to be visually recognized in the front view. On the other hand, the amount of light reflected from the printed layer 5 is relatively small, and thus the pattern shape 51 of the printed layer 5 is less likely to be visually recognized in the front view.

In addition, the luminance Lu2 of the reflected light Ru2 in the oblique direction of the base material 2 becomes lower than the luminance Lu1 of the reflected light Ru1 in the direction of 0 degrees. That is, Lu1>Lu2. This is because light reflected in the oblique direction in the base material 2 is weakened due to reflection between the base material 2 and the light-transmissive layer 3, attenuation due to irregularities of the surface of the base material 2, or the like. For this reason, the amount of light reflected obliquely by the printed layer 5 becomes relatively large, and the pattern shape 51 of the printed layer 5 is likely to be visually recognized. That is, when the luminance of the reflected light Rs2 in the oblique direction of the printed layer 5 is Ls2, and the luminance of the reflected light Ru2 in the oblique direction of the base material 2 is Lu2, Ls2<Lu2, but a difference in luminance therebetween becomes smaller than a difference in luminance between Ls1 and Lu1.

For this reason, in a case where Ls2/Lu2>Ls1/Lu1, and the dial 1 is viewed from the oblique direction, the luminance of the printed layer 5 becomes relatively higher than the luminance of the base material 2 as compared to a case where the dial 1 is viewed in the front view, and thus the pattern shape 51 of the printed layer 5 is likely to be visually recognized.

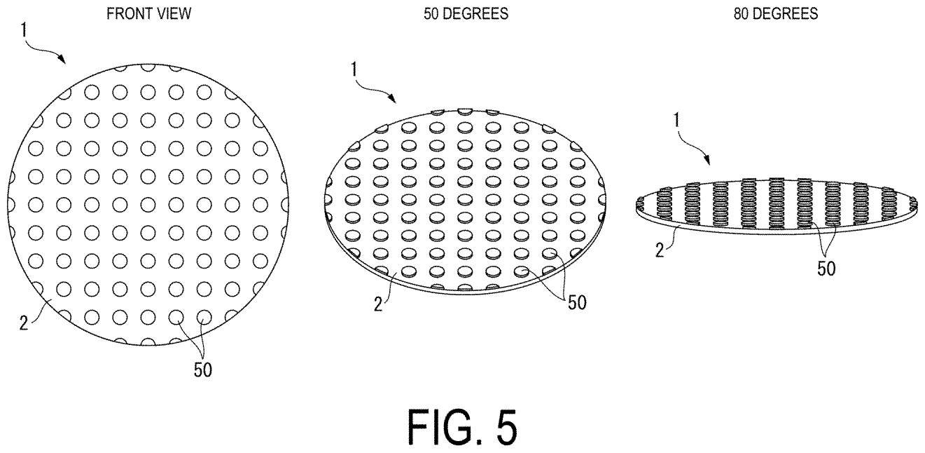

Further, as illustrated in FIG. 5, when comparing the case of the front view of the dial 1 when viewed from the direction of 0 degrees orthogonal to the surface of the dial 1, the case of the perspective view of 50 degrees when viewed from the oblique direction of 50 degrees with respect to the orthogonal direction, and the case of the perspective view of 80 degrees when viewed from the oblique direction of 80 degrees, an exposed area of the ink 50 with respect to an exposed area of the base material 2 is the smallest in the case of the front view, and is the greatest in the case of 80 degrees. For this reason, in the case of 80 degrees, the pattern shape 51 of the printed layer 5 is more likely to be visually recognized compared to the front view.

At this time, an interval between dots of the ink 50 forming the pattern shape 51 of the printed layer 5 is preferably larger than one time and smaller than three times the diameter of the dot. That is, in a case where the interval between the dots is equal to or less than one time the diameter of the dot, the interval between the dots is small, and thus it is difficult to visually recognize the pattern shape 21 of the base material 2 particularly when non-transparent ink is used. On the other hand, in a case where the interval between the dots is equal to or greater than three times the diameter of the dot, the interval between the dots is large, and thus the pattern shape 51 may become unclear because the dots are separated from each other even when the dial 1 is viewed in a perspective view. On the other hand, when the interval between the dots is made to be greater than one time and smaller than three times the diameter of the dot, it is possible to visually recognize the pattern shape 21 of the base material 2 when the dial 1 is viewed in a front view and to clearly visually recognize the pattern shape 51 of the printed layer 5 when the dial 1 is viewed in a perspective view.

Note that an angle at which the pattern shape 51 of the printed layer 5 is clearly viewed when the dial 1 is viewed in a perspective view is influenced by an interval between the dots. For example, the example illustrated in FIG. 5 shows a case where the interval between the dots is twice the diameter of the dot. In this case, when viewed from an angle of 50 degrees or more with respect to the orthogonal direction, the pattern shape 51 of the printed layer 5 tends to be viewed clearly. Further, in a case where the interval between the dots is one time the diameter of the dot, the pattern shape 51 of the printed layer 5 tends to be viewed clearly when viewed from an angle of 30 degrees or more with respect to the orthogonal direction, and in a case where the interval between the dots is three times the diameter of the dot, the pattern shape 51 of the printed layer 5 tends to be viewed clearly when viewed from an angle of 70 degrees or more with respect to the orthogonal direction. That is, when the interval between the dots with respect to the diameter of the dot decreases, the pattern shape 51 of the printed layer 5 becomes clear even when the angle of the dial 1 in a perspective view with respect to the orthogonal direction is small. When the interval between the dots increases, the pattern shape 51 of the printed layer 5 does not become clear when the angle of the dial 1 in a perspective view with respect to the orthogonal direction is not large.

Note that the light-transmissive layer 3 and the liquid repellent layer 4 formed at the surface of the base material 2 may be formed at the entire surface of the base material 2 or may be partially formed. In addition, the printed layer 5 formed at the surface of the liquid repellent layer 4 may be formed at the entire surface of the liquid repellent layer 4, or may be partially formed.

Decoration Example

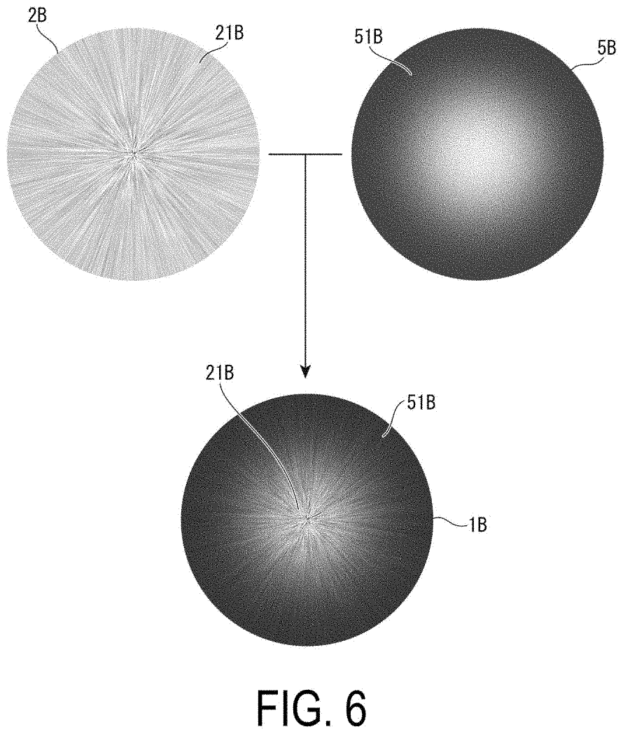

FIG. 6 illustrates a dial 1B in which a printed layer 5B is laminated on a surface side of a base material 2B, as a first decoration example. In the example of FIG. 6, a radial pattern shape 21B is formed in a base material 2B as a base. A pattern shape 51B of the printed layer 5B is set by a dot pattern of ink 50, and the dot pattern is set such that the density of dots is low in a central portion, and the density of dots increases toward a peripheral portion.

For this reason, when the printed layer 5 is formed at the surface side of the base material 2B, as illustrated in the dial 1B of FIG. 6, the pattern shape 21B of the base material 2B is displayed because the density of dots of the ink 50 is low in a central portion of the dial 1B, while the pattern shape 21B of the base material 2B is inconspicuously displayed, and the pattern shape 51B of the printed layer 5B is conspicuously displayed because the density of dots is high in a peripheral portion of the dial 1B.

Note that, in a case where transparent ink is used as the ink 50, the pattern shape 21B of the base is visually recognized through the ink 50 in the peripheral portion of the dial 1B, and thus it is possible to realize a design in which the pattern shape 21B and the pattern shape 51B are combined with each other.

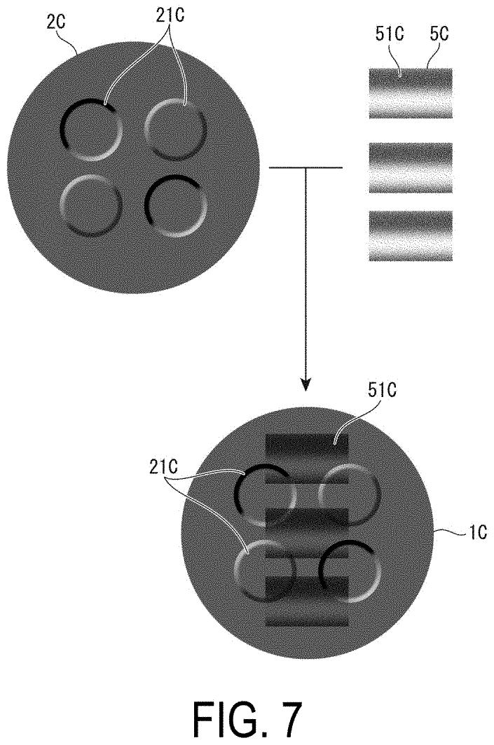

FIG. 7 illustrates a dial 1C in which a printed layer 5C is laminated on a surface side of a base material 2C, as a second decoration example. In the example of FIG. 7, a circular pattern shape 21C having a convex portion and a concave portion is formed in the base material 2C. A pattern shape 51C of the printed layer 5C is formed by a dot pattern of the ink 50, and is set as a pattern that has a density of dots changing in an up-down direction in FIG. 7 and is continuous in a band shape in a right-left direction. For this reason, when the printed layer 5C is formed on a surface side of the base material 2C, as illustrated in the dial 1C of FIG. 7, the pattern shape 21C of the base material 2C is conspicuously displayed in a portion having a low density of dots of the ink 50, while the pattern shape 21C of the base material 2C is inconspicuously displayed, and the pattern shape 51C is conspicuously displayed in a portion having a high density of dots of the ink 50. Further, the printed layer 5C is partially printed on the surface side of the base material 2C, and the pattern shape 21B of the base material 2C can be directly visually recognized in a portion in which the printed layer 5C is not printed.

In the pattern shapes 51B and 51C, a region having a high density of dots of the ink 50 also includes a portion in which an interval between the dots is equal to or less than one time the diameter of the dot, and a region having a low density of dots also includes a portion in which the interval between the dots is equal to or less than three times the diameter of the dot. That is, the interval between the dots is set by a dot pattern at the time of forming the pattern shape of the printed layer 5.

### Effects of Embodiment

According to the present embodiment, the pattern shapes 51, 51B, and 51C of the printed layers 5, 5B, and 5C are printed by changing the density of dots of the ink 50, and thus the pattern shapes 21, 21B, and 21C of the bases are easily visually recognized in a portion having a low density of dots. On the other hand, in a portion having a high density of dots, the pattern shapes 21, 21B, and 21C of the bases are difficult to visually recognize, and the pattern shapes 51, 51B, and 51C of the printed layers 5, 5B, and 5C are easily visually recognized. For this reason, it is possible to express a complex design by the pattern shapes 21, 21B, and 21C of the bases and the pattern shapes 51, 51B, and 51C of the printed layers 5, 5B, and 5C and to improve design properties of the dials 1, 1B and 1C.

Since the ink 50 of the printed layer 5 is ejected by an inkjet method, the printed layer 5 can be formed using various types of ink 50. For this reason, the pattern shapes 21, 21B, and 21C of the bases are easily visually recognized not only in a portion having a low density of dots of the ink 50 but also in a portion having a high density of dots of the ink 50 by using the transparent ink 50, and it is possible to express a complex design in which the pattern shapes 21, 21B, and 21C of the bases are more utilized.

Since the ink 50 is ejected by an inkjet method to form the pattern shapes 51, 51B, and 51C of the printed layers 5, various pattern shapes 51, 51B, and 51C can be printed by a dot pattern. For this reason, it is possible to form a region in which the pattern shapes 51, 51B, and 51C of the printed layers 5 are easily visually recognized by increasing the density of dots like the pattern shapes 51B and 51C of the dials 1B and 1C or to form a region in which the pattern shapes 21, 21B, and 21C of the bases are easily visually recognized by decreasing the density of dots. Moreover, it is possible to form a pattern shape that is not conspicuous in a front view but can be viewed clearly in a perspective view by appropriately setting the interval between the dots, for example, by making the interval larger than one time and smaller than three times the diameter of the dot.

According to the present embodiment, the liquid repellent layer 4 is formed by performing a liquid repellent treatment on the surface of the light-transmissive layer 3 in the dial 1 for a timepiece, and thus the ink 50 ejected by an inkjet method and landed on the liquid repellent layer 4 does not spread so much and can be attached with a stable diameter, and the pattern shapes 51, 51B, and 51C of the printed layer 5 can be expressed sharply. In addition, since the ink 50 of the printed layer 5 is not absorbed by the light-transmissive layer 3, a distance can be taken between the printed layer 5 and the base material 2, and a pattern shape is formed in each of the printed layer 5 and the base material 2. Thus, it is possible to express a complex design having a stereoscopic effect and a depth in the dial 1 and to improve design properties of the dial 1.

### Other Embodiments

Note that the present disclosure is not limited to the embodiments described above, and various modifications can be made within the scope of the present disclosure.

For example, in the embodiments described above, the printed layer 5 is laminated on the surface of the base material 2 through the light-transmissive layer 3 and the liquid repellent layer 4, but the ink 50 may be directly ejected onto the surface of the base material 2 to form the printed layer 5 without providing the light-transmissive layer 3 and the liquid repellent layer 4.

In addition, a light transmissive resin may be further laminate on the surface of the printed layer 5. In this case, the printed layer 5 an be protected by the light transmissive resin.

Further, a water repellent layer may be formed at the surface of the light transmissive resin, ink may be ejected onto the surface of the water repellent layer to form a printed layer, and two printed layers may be provided with a light-transmissive layer interposed therebetween. In this case, in addition to the pattern shape of the base of the base material 2, pattern shapes of the printed layers can be superimposed on each other, and thus it is possible to realize a complex design with a three-dimensional effect and depth.

In the dial, a combination of the color or pattern of the pattern shape of the base material 2 serving as a base and the color or pattern of the pattern shape of the printed layer 5 can be appropriately set in accordance with the design of the dial. For this reason, the color of a base in a case where silver nanoparticle ink is used as the ink 50 is not limited to a dark color, and the color of a base in a case where transparent ink such as titanium oxide ink is used is not also limited to the similar color to that of the ink.

A lyophilic treatment may be performed before a liquid repellent treatment is performed on the surface of the light-transmissive layer 3. The lyophilic treatment can be executed, for example, by emitting ultraviolet light, using atmospheric plasma using oxygen gas, or the like. By performing the lyophilic treatment, the surfaces of the light-transmissive layer 3 can be cleaned, and thus the liquid repellent layer 4 can be formed uniformly by the liquid repellent treatment.

The thickness dimensions of the light-transmissive layer 3 may be set appropriately in practice. A distance between the pattern shape 21 of the base material 2 and the pattern shape 51 of the printed layer 5 changes depending on the thickness dimensions of the light-transmissive layer 3, and thus a stereoscopic effect and a feeling of depth can be adjusted.

### SUMMARY OF PRESENT DISCLOSURE

A dial decoration method of the present disclosure is a dial decoration method including a base formation step of forming a pattern shape in a base material and using the pattern shape as a base, and a printed layer formation step of forming a printed layer on a surface side of the base, and the printed layer formation step includes printing a pattern shape, to form the printed layer, by changing a density of a plurality of dots of ink ejected by an inkjet method.

According to the present disclosure, since the pattern shape of the printed layer is printed by changing the density of dots of the ink, the pattern shape of the base is easily visually recognized in a portion having a low density of dots, and the pattern shape of the base is difficult to visually recognize and the pattern shape of the printed layer is easily visually recognized in a portion having a high density of dots, whereby it is possible to express a complex design with the pattern shape of the base and the pattern shape of the printed layer and to improve a design property of the dial.

In the dial decoration method of the present disclosure, it is preferable that the printed layer formation step include ejecting transparent ink to form the printed layer.

According to the present disclosure, by using transparent ink as the ink of the printed layer, the pattern shape of the base is easily visually recognized not only in a portion having a low density of dots of the ink but also in a portion having a high density of dots, and it is possible to express a complex design in which the pattern shape of the base is more utilized.

In the dial decoration method of the present disclosure, it is preferable that an interval of the dots of the ink be greater than one time and smaller than three times a diameter of the dot.

According to the present disclosure, the interval of the dots is made greater than one time and smaller than three times the diameter of the dot, and thus it is possible to make the pattern shape of the printed layer to be viewed more clearly when inclined at a predetermined angle from a direction orthogonal to the surface of the dial.

In addition, since the interval between the dots is larger than one time the dot diameter, it is possible to visually recognize the pattern shape of the base layer even when non-transparent ink is used. In addition, since the interval between the dots is smaller than three times the dot diameter, it is possible to recognize the pattern shape based on the pattern of the dot.

In the dial decoration method of the present disclosure, it is preferable that the transparent ink be titanium oxide ink.

According to the present disclosure, the pattern shape of the base material can also be visually recognized by transmission by using titanium oxide ink. In particular, the titanium oxide ink is white transparent ink, and thus it is possible to make it easy to visually recognize the pattern shape of the base material even in a region having a high density of dots of the ink and to express a complex design by the pattern shapes of the base material and the printed layer being viewed to overlap each other.

In the dial decoration method of the present disclosure, it is preferable that the ink be silver nanoparticle ink or titanium oxide ink.

According to the present disclosure, since silver nanoparticle ink or titanium oxide ink is used, it is possible to use ink that has been put into practical use as a piezo-type inkjet printer and to realize a decoration method at low cost.

A dial of the present disclosure includes a base material having a surface on which a pattern shape used as a base is formed, and a printed layer formed on a surface side of the base, wherein a pattern shape is printed on the printed layer by changing a density of dots of ink ejected by an inkjet method.

According to the present disclosure, since the pattern shape of the printed layer is printed by changing the density of dots of the ink, and thus the pattern shape of the base is easily visually recognized in a portion having a low density of dots, and the pattern shape of the base is difficult to visually recognize in a portion having a high density of dots, whereby it is possible to express a complex design with the pattern shape of the base and the pattern shape of the printed layer.

In the dial of the present disclosure, it is preferable that the base be formed in a dark color, the printed layer be formed by silver nanoparticle ink, and an interval between dots of the silver nanoparticle ink be greater than one time and smaller than three times a diameter of the dot.

According to the present disclosure, since the base is formed in a dark color such as black or navy blue, that is, a color that is different from white depending on the brightness and saturation, silver nanoparticle ink, which is silver ink, is easily visually recognized, and the pattern shape of the printed layer can also be easily visually recognized. In addition, although the silver nanoparticle ink is non-transparent ink, a region in which an interval between dots is larger than one time and smaller than three times the diameter of the dot is set, and thus it is possible to visually recognize the pattern shape of the base layer by an interval between dots and to make it easy to view a pattern shape formed using silver nanoparticle ink when the dial is viewed from an oblique direction.

In the dial of the present disclosure, it is preferable that the printed layer be formed by transparent ink, the base be formed in the similar color to that of the transparent ink, and the printed layer be partially formed at a surface of the base.

According to the present disclosure, since the base and the ink are formed in the similar color, the color of the base and the color of the transparent ink are viewed to overlap each other, and thus it is possible to express a high-quality pattern shape in which two types of textures are mixed. In addition, since the printed layer is partially formed at the surface of the base, and the base and the ink are formed in the similar color, the color tone of a portion in which the printed layer is not provided and the base is exposed and the color tone of a portion in which the base provided with the printed layer and the ink overlap each other are made similar to each other, and a high-quality pattern shape can be expressed in this respect.

What is claimed is:

1. A dial decoration method, comprising:
a base formation step of forming a pattern shape on a base material and using the pattern shape as a base; and
a printed layer formation step of forming a printed layer on a surface side of the base,
wherein the printed layer formation step includes printing a pattern shape, to form the printed layer, by changing a density of a plurality of dots of ink ejected by an inkjet method.

2. The dial decoration method according to claim 1, wherein the printed layer formation step includes ejecting transparent ink to form the printed layer.

3. The dial decoration method according to claim 1, wherein
an interval of the plurality of dots of the ink is greater than one time a diameter of a dot of the plurality of dots and smaller than three times the diameter of the dot.

4. The dial decoration method according to claim 2, wherein
the transparent ink is titanium oxide ink.

5. The dial decoration method according to claim 3, wherein
the ink is silver nanoparticle ink or titanium oxide ink.

6. A dial comprising:
a base material having a surface on which a pattern shape used as a base is formed; and
a printed layer formed on a surface side of the base,
wherein a pattern shape is printed on the printed layer by changing a density of a plurality of dots of ink ejected by an inkjet method.

7. The dial according to claim 6, wherein
the base is formed in a dark color,
the printed layer is formed using silver nanoparticle ink, and
an interval between a plurality of dots of the silver nanoparticle ink is greater than one time a diameter of a dot of the plurality of dots and smaller than three times the diameter of the dot.

8. The dial according to claim 6, wherein
the printed layer is formed using transparent ink,
the base is formed in a similar color to the color of the transparent ink, and
the printed layer is partially formed at a surface of the base.
